(19) United States
(12) Patent Application Publication
(10) Pub. No.: US 2024/0353804 A1
(43) Pub. Date: Oct. 24, 2024

(54) COMPUTER-IMPLEMENTED METHOD AND APPARATUS FOR GENERATING A HYBRID ARTIFICIAL INTELLIGENCE ALGORITHM

(71) Applicant: Robert Bosch GmbH, Stuttgart (DE)

(72) Inventors: Alexander Fischer, Nordhausen (DE); Stephan Rhode, Karlsruhe (DE)

(21) Appl. No.: 18/633,403

(22) Filed: Apr. 11, 2024

(30) Foreign Application Priority Data
Apr. 19, 2023 (DE) 10 2023 203 586.3

(51) Int. Cl. G05B 13/02

(52) U.S. Cl. CPC G05B 13/027

(57) ABSTRACT

A computer-implemented method for generating a hybrid artificial intelligence algorithm. The method includes: providing a system state vector that includes at least two system states of the physical system, wherein at least one of the at least two states can be calculated by at least one analytical and/or statistical equation, and wherein at least one other of the at least two states can be calculated by at least one artificial intelligence algorithm to be ascertained; carrying out at least one automatic learning method for ascertaining a plurality of artificial intelligence algorithms using which at least the other of the at least two states can be calculated in each case; and selecting at least one artificial intelligence algorithm from the plurality of artificial intelligence algorithms as a function of at least one selection criterion to generate the hybrid artificial intelligence algorithm coupled with the at least one equation.

### FIELD

The present invention relates to a computer-implemented method and an apparatus for generating a hybrid artificial intelligence algorithm.

### BACKGROUND INFORMATION

In recent years, the industrial environment, particularly the automotive industry, has changed significantly and is increasingly focused on the integration of AI technologies. In particular, hybrid automated machine learning methods (so-called Auto-ML methods) have proven to be a promising technology for improving the performance of self-driving cars. These models combine both statistical and/or analytical methods and artificial intelligence methods to create a robust and accurate model that is able to describe complex scenarios and/or states of a physical system and, in particular, to make quick decisions and/or choices in real time.

Traditionally, the architecture of neural networks has been designed manually by designing, training, and testing different architectures to find the best one. NAS automates this process by using a search space function that represents a specific architectural space that constrains the search. An evaluation function is then used to measure the performance of each architecture by testing it on training data. Finally, an optimization function is used to find the best architecture in the search space.

Auto-ML methods have been known since the early 2000s and allow for the automatic creation of machine learning models. The goal of all Auto-ML methods is to minimize user input for creating the ML model. This reduces development costs and improves the results of automated model creation. This is due in particular to the fact that ML model creation is automated and that an optimal ML model can be searched for in a larger search space compared to manual model creation. Initially, Auto-ML methods were mostly focused on classic machine learning models such as neural networks (NNs for short), Gaussian decision processes (GPs for short) and/or decision trees. In particular, the goal was to find the right model type and/or the right model structure and/or the most optimal model hyperparameters, depending on the task. For example, the Auto-ML method “Neural Architecture Search” from the scientific article Pengzhen Ren, Yun Xiao, Xiaojun Chang, Po-yao Huang, Zhihui Li, Xiaojiang Chen, and Xin Wang. 2021. “A Comprehensive Survey of Neural Architecture Search: Challenges and Solutions.” ACM Comput. Surv. 54, 4, Article 76 (May 2022), 34 pages. https://doi.org/10.1145/3447582 is for automatically finding the optimal model type and/or the optimal model structure and/or the most optimal model hyperparameter.

Neural Architecture Search (NAS) is an automated process in which the architecture of neural networks is automatically searched to find an optimal architecture for a certain task. Essentially, the goal is to develop a machine that independently designs the structure of a neural network instead of humans doing it manually.

Furthermore, Auto-ML methods are already used to find hybrid ML models. Hybrid ML models are, for example, physics-informed neural networks (NNs) that are based on classical NNs, but whose cost function is supplemented by physical conservation equations that are treated as penalty term(s). Alternatively, additively linked, hybrid ML models are also described in the scientific article Nikolay O. Nikitin, Ilia Revin, Alexander Hvatov, Pavel Vychuzhanin, Anna V. Kalyuzhnaya, “Hybrid and automated machine learning approaches for oil fields development: The case study of Volve field, North Sea, Computers & Geosciences,” Volume 161, 2022, 105061, ISSN 0098-3004, https://doi.org/10.1016/j.cageo.2022.105061. In the latter reference, it is described to design static hybrid ML models in such a way that, in addition to various standard ML models that are used in an ensemble to solve the same prediction problem, a physics-based modeling component is also taken into account in the solution. One disadvantage of this conventional ensemble method is that solving the prediction problem using different ML models is very computationally expensive, as the same prediction problem has to be solved several times using different ML models.

Auto-ML methods can be used in particular in the field of vehicle dynamics models.

Conventional vehicle dynamics models are based on physical equations and can vary in complexity. Vehicle dynamics models are used, for example, in controllers of lane departure warning systems or evasive steering assistants. Well-known models are the single-track model and the roll model for describing the vehicle dynamics of a vehicle. It is conventional to adapt these models to data by optimizing the model parameters. If the optimization of the model parameters does not yet provide the desired accuracy, the system switches from a low model complexity (e.g. linear single-track model) to the next higher complexity (e.g. single-track model with nonlinear tire characteristic curve). However, this change in model complexity is costly. A new implementation is required and the model parameters must be optimized again. These conventional physical models represent the group of so-called “white-box” or “gray-box” models.

On the other hand, vehicle dynamics models based on “black-box” models are known. These models are purely data-based and have, for example, neural networks and/or Gaussian processes to find parameters. The complexity of these models can easily be changed by the number of neurons in the NNs or by the number of kernel functions in sparse GPs. Optimizing the models to the reference data is often an integral part of model creation. A major disadvantage is the large amount of memory required and the usually inaccurate extrapolation of this model class. Data generation requires more effort than parameter optimization of previous physical models.

The aforementioned hybrid ML models are located between the aforementioned model classes. These hybrid ML models are a mixture of physically inspired differential equations and neural networks and/or differential equations. Physical components that are based, for example, on energy conservation or pure kinematics and do not contain adjustable parameters can be defined as ordinary differential equations (ODEs). The neural network no longer has to model these OED components, but is applied to components with unknown physics or with adjustable parameters. This results in a hybrid ML model that combines the advantages of physical models and data-driven ML models. Compared to pure “black-box” models, the hybrid model usually requires less memory.

An object of the present invention is to provide an improved computer-implemented method and/or an improved apparatus for automatically generating a hybrid artificial intelligence algorithm.

The object may achieved by a computer-implemented method for generating a hybrid artificial intelligence algorithm according to features of the present invention. Furthermore, the object may be achieved by an apparatus for generating a hybrid artificial intelligence algorithm according to features of the present invention.

### SUMMARY

According to the present invention, a computer-implemented method for generating a hybrid artificial intelligence algorithm is proposed. The artificial intelligence algorithm generated in this way can be used to model and/or regulate and/or control and/or adjust and/or modify the dynamic system behavior of a physical system. According to an example embodiment of the present invention, the method comprises the following steps:

Providing a system state vector that comprises at least two system states of the physical system, wherein at least one of the at least two states can be calculated by means of at least one analytical and/or statistical equation that preferably satisfies a predetermined complexity criterion, and wherein at least one other of the at least two states can be calculated by means of at least one artificial intelligence algorithm to be ascertained; carrying out at least one automatic learning method for ascertaining a plurality of artificial intelligence algorithms by means of which in each case the at least other of the at least two states can be calculated; and selecting at least one artificial intelligence algorithm from the plurality of artificial intelligence algorithms as a function of at least one selection criterion to generate the hybrid artificial intelligence algorithm coupled with the at least one equation.

It is understood that the steps according to the present invention as well as other optional steps do not necessarily have to be carried out in the order shown, but can also be carried out in a different order. Other intermediate steps can also be provided. The individual steps can also comprise one or more sub-steps without departing from the scope of the method according to the present invention.

Furthermore, according to an example embodiment of the present invention, an apparatus for generating a hybrid artificial intelligence algorithm (hereinafter also referred to as: hybrid AI algorithm) is provided in accordance with the present invention. The artificial intelligence algorithm generated in this way can be used to model and/or regulate and/or control and/or adjust and/or modify the dynamic system behavior of a physical system. According to an example embodiment of the present invention, the apparatus has a providing device configured to provide a system state vector that comprises at least two system states of the physical system, wherein at least one of the at least two states can be calculated by means of at least one analytical and/or statistical equation that preferably satisfies a predetermined complexity criterion, and wherein at least one other of the at least two states can be calculated by means of at least one artificial intelligence algorithm to be ascertained. Furthermore, the apparatus has an evaluating and computing device designed to carry out the following steps: carrying out at least one automatic learning method (hereinafter also referred to as: Auto-ML method) for ascertaining a plurality of artificial intelligence algorithms by means of which in each case the at least other of the at least two states can be calculated; and selecting at least one artificial intelligence algorithm from the plurality of artificial intelligence algorithms as a function of at least one selection criterion to generate the hybrid artificial intelligence algorithm coupled with the at least one equation.

The hybrid AI algorithm generated according to the present invention is characterized by good interpretability, low memory requirements and computational requirements, good adaptability to reference data, and good extrapolation.

According to an example embodiment of the present invention, the application of Auto-ML methods has been extended in such a way that a dynamic, hybrid AI algorithm for describing a dynamic system behavior of a physical system can be selected from a large number of AI algorithms, which allows the system behavior to be described in the most accurate and computationally efficient way possible. An extension therefore concerns the modeling and prediction of dynamic behavior. In addition to suitable Auto-ML models (e.g. RNN, LSTM), physics-based dynamic model components, preferably defined by differential equations, are also preferred in the hybrid AI algorithm for this purpose. RNN stands for “Recurrent Neural Network” and is a type of neural network used in artificial intelligence and machine learning applications. Unlike other neural network architectures, an RNN can retain or “remember” states, which allows the network to respond to previous inputs or events and use information from previous steps. LSTM preferably stands for “Long Short-Term Memory” and is a special type of recurrent neural network (RNN). Like other RNNs, LSTM has a feedback loop that allows the network to retain and access information from previous steps. However, unlike traditional RNNs, LSTM can effectively handle long dependencies between previous inputs by introducing a memory in the loop.

The method according to the present invention and the apparatus not only additively complement the physically modeled part of the system behavior (represented by the at least one equation) with an AI-based correction term, but the hybrid AI algorithm according to the present invention is designed in such a way that the analytical and/or statistical part can be linked to the AI-based part in different ways (not only purely additively). Many different interconnection topologies between physics model components and ML model components are possible. The relative proportion of physics-based equations preferably depends on how well the system behavior to be modeled has been researched and/or described. In some cases, it is desirable to predict only one specific variable, for example a state variable, with an AI algorithm or an ML model, because it is known, for example, that description with basic equations is very complex and/or computationally expensive. In other cases, due to a lack of prior physical knowledge, it can be preferred to reconstruct the entire state vector from data and optionally to exclude only individual states, for example integration chains, therefrom.

The term “hybrid AI algorithm” is preferably to be understood such that a part of the algorithm describing the system behavior can be unambiguously calculated by classical methods of analytics and/or statistics without necessarily having to train and/or use an AI algorithm for this purpose. The corresponding system state can therefore be calculated deterministically using at least one analytical and/or statistical equation. Another part of the system behavior, on the other hand, preferably cannot be described in a simple way by analytical and/or statistical methods and/or metrics, so that at least one AI algorithm should be used for this part. Such an AI algorithm optimized for the system behavior can then be found automatically by Auto-ML methods according to the present invention and does not necessarily have to be selected and/or designed by a user. The Auto-ML method solves the underlying problem of how to describe the at least other of the at least two system states preferably in a plurality of ways, for example by designing and/or specifying different AI algorithms that solve the same basic problem in different ways. This results in a plurality of AI algorithms, from which the AI algorithm used for the hybrid AI algorithm is then selected based on the selection criterion. The selection is preferably automated, but can also be carried out manually by a user. The plurality of AI algorithms can, for example, have neural ordinary differential equations (neural ODEs).

A “neural ODE” (ODE stands for “Ordinary Differential Equations”) is an approach for using neural networks to solve differential equations. In contrast to traditional numerical methods for solving differential equations, which preferably integrate the system step by step, a neural ODE model uses a neural network to approximate the solution of the differential equation. A neural ODE model preferably uses a continuous-depth neural network that is continuously parameterized and approximates the solution of the differential equation system. The network preferably uses the “adjoint method” to calculate the gradients of the solution with respect to the initial conditions and the parameters, which allows an effective optimization of the parameters.

The term “dynamic system behavior” refers to the way in which a physical system changes over time. Dynamic systems can exist in various fields such as physics, engineering, biology, and economics. The method according to the present invention and the apparatus according to the present invention can therefore be used in just as many fields. In general, dynamic system behavior describes how a system reacts to changes in its input variables and/or to internal state changes. These changes can be discrete and/or continuous signals and/or events. The behavior of the system can be linear and/or nonlinear and can be described by a plurality of mathematical models, in particular differential equations, difference equations and control systems, and/or AI algorithms.

The system state vector preferably describes the complete or partial state of a dynamic system at a specific point in time. It preferably has information about a plurality of, preferably all, relevant variables and/or states of the physical system, which are preferred for describing the behavior of the system. This can comprise both the physical, in particular time-variable, states of a system (e.g., position, speed, acceleration, etc.) and the internal states of the system (e.g. energy storage, internal pressures, temperature, etc.). The system state vector is preferably represented as a column vector consisting of a certain number of elements representing the different state variables of the system. By integrating the state changes over time, the system state vector can preferably be used to predict the behavior of the system in the future.

In a preferred embodiment of the present invention, the at least one automatic learning method comprises a neural architecture search, NAS, and/or solution finder for solving ordinary differential equations and/or a hyperparameter search and/or a model structure search. Thus, an Auto-ML method is disclosed that can also find the best model structure in addition to model hyperparameters, in particular for hybrid dynamic AI models. In addition, the parameters of the differential equation solver used by the AI model are optimized. The RNNs and/or LSTMs described above can also be used.

In a preferred embodiment of the present invention, the selection criterion is determined by a predetermined complexity measure of each artificial intelligence algorithm of the plurality of artificial intelligence algorithms. One measure of such complexity can be, for example, the number of intermediate layers (so-called hidden layers) of a neural network (NN for short) that represent each AI algorithm. Alternatively or additionally, the complexity can be determined by evaluating the hyperparameters set for the particular neural network. A transit time through the particular NN can also be understood as a measure of complexity. Other criteria specific to AI algorithms are also possible as complexity measures.

For example, in a preferred embodiment of the present invention, the selection criterion can be determined by a predetermined amount of storage space and/or by an execution time and/or by an Akaike information criterion of each artificial intelligence algorithm of the plurality of artificial intelligence algorithms. In particular, the available storage space may be limited, for example, in the subsequent application of the hybrid AI algorithm generated and/or ascertained according to the present invention due to application-specific hardware requirements. If the hybrid AI algorithm is to be executed on a control unit of a motor vehicle, for example, the available storage space can be determined by the storage capacity of the control unit. A similar situation can occur with respect to the execution time if, for example, a processor of a control unit on which such a hybrid AI algorithm is to be implemented is determined to a certain extent due to its clock frequency and/or its number of cores and/or its cache size and/or its architecture and/or its heat generation and/or its power supply, as a result of which the execution time may be significantly increased. The Akaike information criterion (AIC) is a statistical method used for model selection in multivariate statistics. The AIC compares the goodness of fit of different statistical models to data and evaluates not only the goodness of fit to the data, but also the complexity of the model. The goal is to select the model that best explains the data but is not too complex. The AIC preferably evaluates the goodness of a model based on the ratio of information loss to the number of estimation parameters. The AIC can preferably be used together with other methods such as the Bayes factor for model selection.

In a preferred embodiment of the present invention, the at least one analytical and/or statistical equation is described by at least one differential equation. A differential equation is a mathematical equation that describes a relationship between a function and its derivatives. A differential equation is therefore an equation that defines a function in terms of its derivatives. Differential equations are used to model dynamic systems in which the change in one variable depends on the change in one or more other variables.

In a preferred embodiment of the present invention, the at least one analytical and/or statistical equation comprises an equation term that can be calculated by means of an artificial intelligence algorithm to be ascertained. It is possible, for example, that not the entire equation can be solved by analytical and/or statistical calculation algorithms, but instead comprises, for example, a (residual) term that represents physically highly complex relationships that cannot be solved analytically or only with very high computational effort. Such a (residual) term can then be trained using an AI algorithm, for example, so that the equation as a whole is described by a hybrid AI algorithm. This can be selected and determined in accordance with the present invention.

In a preferred embodiment of the present invention, the plurality of artificial intelligence algorithms is ascertained by carrying out the at least one automatic learning method in a parallelized manner. Parallelization is preferably a concept in computer science and computer architecture in which a problem or task is divided into a plurality of processes or threads that can be executed simultaneously in order to reduce execution time and improve efficiency. This allows the different automatic learning methods for generating the plurality of AI algorithms to be applied in parallel to generate the plurality of AI algorithms faster and more efficiently.

In a preferred embodiment of the present invention, the plurality of artificial intelligence algorithms is ascertained taking into account available computing resources, which are preferably included as a loss function in the model ascertainment. In other words, the computer used to generate the hybrid AI algorithm may limit the generation of the plurality of AI algorithms by its intrinsic computing resources so that, for example, some highly accurate but highly complex AI algorithms are not ascertained for later selection because these AI algorithms would exceed the computing resources of the computer.

In a preferred embodiment of the present invention, the at least two states can be described by physical measured values and/or input data and/or output data and/or manipulated variables and/or sensor data. Physical constants can of course also be used to describe states. For example, in the case of a vehicle dynamics simulation, a yaw rate and/or a slip angle and/or a steering angle can be modeled. The dynamic system behavior of the yaw rate and/or the slip angle and/or the steering angle can be described, for example, by at least two states, wherein one of the at least two states can be described in a purely analytical manner and another of the at least two states is physically highly complex because, for example, a plurality of tire parameters or the like are involved in describing the state. The latter state can then be mapped by an AI algorithm, which is found according to the present invention by an Auto-ML method. The result is the hybrid AI algorithm for the yaw rate and/or the slip angle and/or the steering angle.

In a preferred embodiment of the present invention, the physical system is or describes or simulates or models a motor vehicle or a heat pump. The list given here is purely exemplary and not restrictive. The method and/or apparatus according to the present invention can be used in various fields of mechanics and/or electrical engineering and/or automotive engineering and/or aerospace engineering and/or biotechnology and/or medical technology whenever a physical system has a dynamic system behavior that can be described by analytical and/or AI-based methods.

In a preferred embodiment of the present invention, the dynamic system behavior is described by a vehicle dynamics model of a motor vehicle or a dynamic energy distribution model of a heat pump. In principle, however, the method and/or apparatus according to the present invention is not limited to a specific dynamic system behavior, but can be used to describe various dynamic system behaviors of a physical system.

According to an example embodiment of the present invention, a physical system, in particular a motor vehicle or a heat pump, is provided, the dynamic system behavior of which is at least partially modeled and/or regulated and/or controlled and/or adjusted and/or modified by a hybrid artificial intelligence algorithm, wherein the hybrid artificial intelligence algorithm is generated and/or provided and/or selected by means of the method according to the present invention according to any embodiment. The hybrid AI algorithm ascertained according to the present invention can be used in lane departure warning systems and/or generally in software functions in the field of autonomous driving. In addition, the modeling approach according to the present invention is suitable for generating the hybrid AI algorithm for other physical problems, for example in the field of heat pumps, etc. In other fields, the physical component of the hybrid AI model is to be adapted according to each system behavior.

According to an example embodiment of the present invention, a computer program having program code is also provided to carry out at least parts of the method according to the present invention in any of its embodiments when the computer program is executed on a computer. In other words, according to the present invention, a computer program (product) comprising commands that, when the program is executed by a computer, cause the computer to carry out the method/steps of the method according to the present invention in any of its embodiments.

According to an example embodiment of the present invention, a computer-readable data carrier having program code of a computer program is proposed to carry out at least parts of the method according to the present invention in any of its embodiments when the computer program is executed on a computer. In other words, the present invention relates to a computer-readable (storage) medium comprising commands that, when executed by a computer, cause the computer to carry out the method/steps of the method according to the present invention in any of its embodiments.

The described embodiments and developments of the present invention can be combined with one another as desired.

Further possible embodiments, developments and implementations of the present invention also include combinations not explicitly mentioned of features of the present invention described above or in the following relating to the exemplary embodiments.

### BRIEF DESCRIPTION OF THE DRAWINGS

The figures are intended to impart further understanding of example embodiments of the present invention. They illustrate embodiments and, in connection with the description, serve to explain principles and concepts of the present invention. Other embodiments and many of the mentioned advantages are apparent from the figures. The illustrated elements of the figures are not necessarily shown to scale relative to one another.

FIG. 1 shows a schematic flowchart of an exemplary embodiment of the method according to the present invention.

FIG. 2 shows a schematic block diagram of an exemplary embodiment of the method according to the present invention.

FIG. 3 shows a schematic vehicle dynamics model of a motor vehicle.

FIG. 4 shows an example of a hybrid artificial intelligence algorithm that is generated based on a physical model to describe driving dynamics.

FIG. 5 shows a diagram describing a time course of various parameters of a vehicle dynamics model by means of a conventional physical single-track model.

FIG. 6 shows a diagram describing a time course of various parameters of a vehicle dynamics model by means of a hybrid algorithm generated according to the present invention.

In the figures, identical reference signs denote identical or functionally identical elements, parts or components, unless stated otherwise.

### DETAILED DESCRIPTION OF EXAMPLE EMBODIMENTS

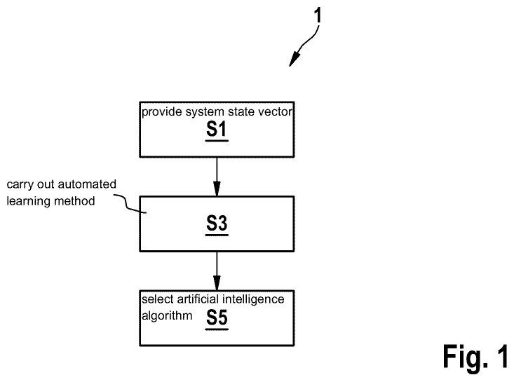

FIG. 1 shows a schematic flowchart of a method for generating a hybrid artificial intelligence algorithm by means of which a dynamic system behavior of a physical system can be modeled and/or regulated and/or controlled and/or adjusted and/or modified.

In any embodiment, the method can be carried out at least partially by an apparatus 1 that can comprise, for this purpose, multiple components (not shown in detail), for example one or more providing devices and/or at least one evaluating and computing device. It is self-evident that the providing device can be designed together with the evaluating and computing device, or can be different therefrom. Furthermore, the system can comprise a storage device and/or an output device and/or a display device and/or an input device.

According to an example embodiment of the present invention, the computer-implemented method has at least the following steps:

In a step S1, a system state vector that comprises at least two system states of the physical system is provided, wherein at least one of the at least two states can be calculated by means of at least one analytical and/or statistical equation that preferably satisfies a predetermined complexity criterion, and wherein at least one other of the at least two states can be calculated by means of at least one artificial intelligence algorithm to be ascertained.

In a step S3, at least one automatic learning method is carried out to ascertain a plurality of artificial intelligence algorithms by means of which in each case the at least other of the at least two states can be calculated.

In a step S5, at least one artificial intelligence algorithm is selected from the plurality of artificial intelligence algorithms as a function of at least one selection criterion to generate the hybrid artificial intelligence algorithm coupled with the at least one equation.

The structure of a hybrid dynamic AI algorithm can preferably be described as follows:

$$dx = [ Ax + B ; NN ( u , x , t ) ] \hat{} Tdt$$

A dynamic of the temporal evolution of the at least two states described by the right-hand side of equation 1 is composed of at least one physically modeled component Ax+B and at least one AI-based trained component NN(u, x, t).

The at least one physical component and the at least one AI-based trained component are coupled to one another by the state vector x. In contrast to the related art, the coupling does not need to be additive. In addition, AI-based trained components can also preferably supplement a physical equation such as Ax+B, for example in the manner of: Ax+B(B₁+NN(B₂)). Preferably, therefore, one of the at least two states can be modeled in a mixed physical and AI-based manner. This discovery of the variety of possible model structures can be solved by applying the extended Auto-ML method according to the present invention.

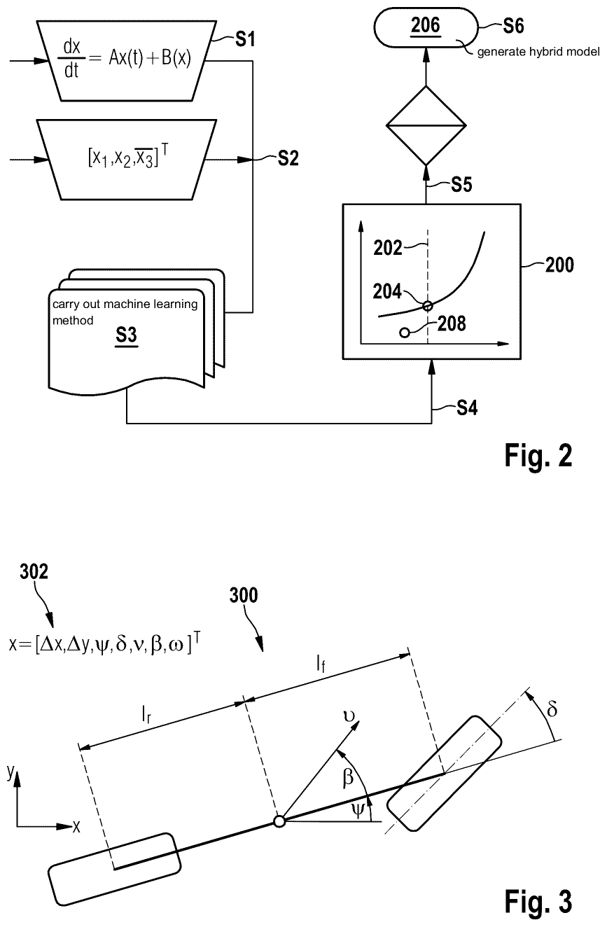

FIG. 2 shows a schematic block diagram of an exemplary embodiment of the method according to the present invention. The system state vector is provided in step S1. Preferably, the physical relationships for describing the dynamic system behavior are provided by analytical and/or statistical equations and/or a state space representation. In an optional step S2, at least one restriction is set for the at least one automatic learning method. For example, only a subset of physical equations can be replaced by an AI algorithm, or supplemented and/or corrected by an AI algorithm. Step S3 is then carried out. In this case, the at least one Auto-ML method preferably optimizes a model structure and/or at least one hyperparameter and/or at least one solver and/or at least one solver setting. Step S3 can preferably be parallelized. In an optional step S4, the plurality of AI algorithms of the solution set of the Auto-ML method can be evaluated, preferably with respect to accuracy and complexity. Model selection criteria such as the Akaike information criterion can preferably be used for this purpose. One result of such an Akaike information criterion is shown schematically in a diagram 200 in FIG. 2. The corresponding accuracy (or 1-error) is plotted on the abscissa and the corresponding complexity on the ordinate. The curve preferably forms a boundary along which a ratio of accuracy to complexity is optimal. For example, a specific AI algorithm can be selected from the plurality of AI algorithms by setting a selection criterion by specifying a certain complexity. Such a selection criterion is shown schematically in FIG. 2 with the reference sign 202. The AI algorithm selected in step S5 for generating a hybrid model 206 is denoted by the reference sign 204 in the diagram 200 in FIG. 2. An example algorithm, which is not selected, is shown in the diagram 200 with the reference sign 208. In step S5, the at least one artificial intelligence algorithm 204 is selected from the plurality of artificial intelligence algorithms as a function of at least one selection criterion 202. In an optional step S6, the hybrid AI algorithm 206 is output and/or generated. In this case, coupling with the at least one equation takes place.

The method according to the present invention can be explained in particular by the use case of generating a hybrid artificial intelligence algorithm 206 for providing a vehicle dynamics model of a motor vehicle with reference to FIGS. 3 to 6.

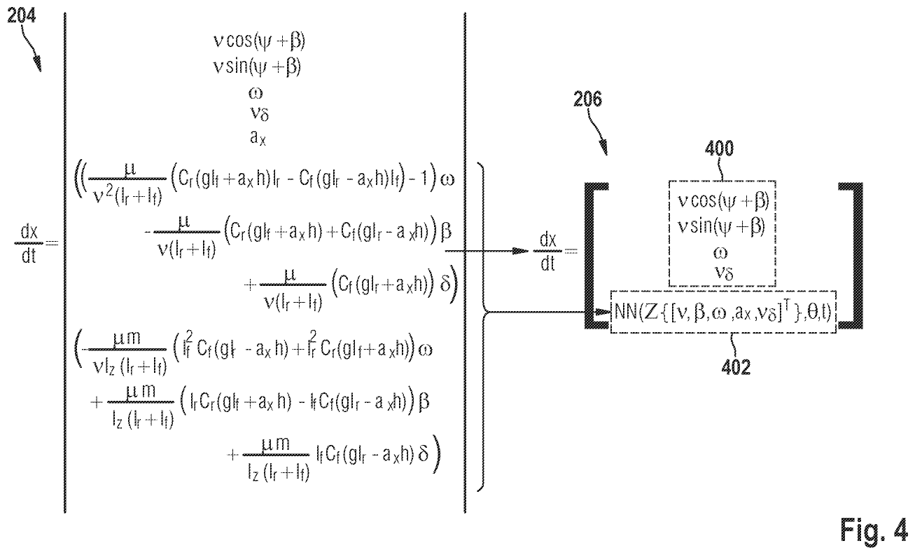

FIG. 3 shows a schematic vehicle dynamics model of a motor vehicle. The motor vehicle represents a special form of a physical system 300. In the present case, the vehicle dynamics model shown is a hybrid single-track model that has good extrapolation via a physical component 400 and is adapted to input data by the complementary AI algorithm component 402 (see FIG. 4). The hybrid AI algorithm 206 generated in this way is more accurate than the underlying physical model 404 (see FIG. 4) with improved extrapolation compared to the purely data-based model 404. The single-track model under consideration is used to model at least two states.

A vehicle acceleration in the longitudinal direction and a steering angle speed are used as inputs. The goal of all the models is to model the future trajectories of the states as accurately as possible for the inputs, as a function of a provided system state vector 302 or start vector comprising the at least two states and/or their time courses.

The differential equation of the purely data-based, linear single-track model 404 is shown in FIG. 4. The model 404 comprises a plurality of vehicle parameters to be optimized, such as the vehicle mass m. In contrast, the structure of the AI-based component 402 can be expressed very compactly, namely:

$$\frac{dx}{dt} = NN ( x , u , θ , t )$$

The neural network or the AI-based component preferably models all derivatives of the states. According to the present invention, the hybrid AI algorithm 206 can be generated therefrom, as shown in FIG. 4.

The first four lines in the vector of state derivatives are identical to the linear single-track model and represent the physical component 400. These relationships are preferably based purely on kinematics and have no unknown physical effects or unknown parameters. The fifth to seventh states are modeled using the AI algorithm 204, for example a neural ODE found and secreted by Auto-ML methods according to the present invention. The AI algorithm 204 preferably receives as input the input signals and, in some cases, states from the previous time step.

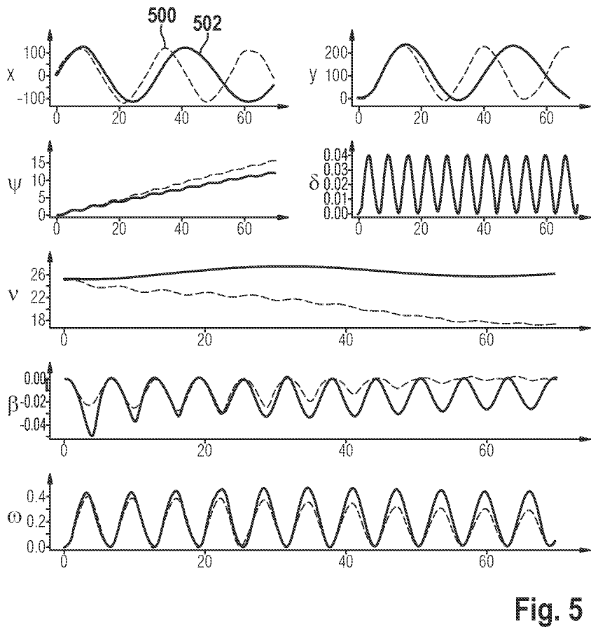

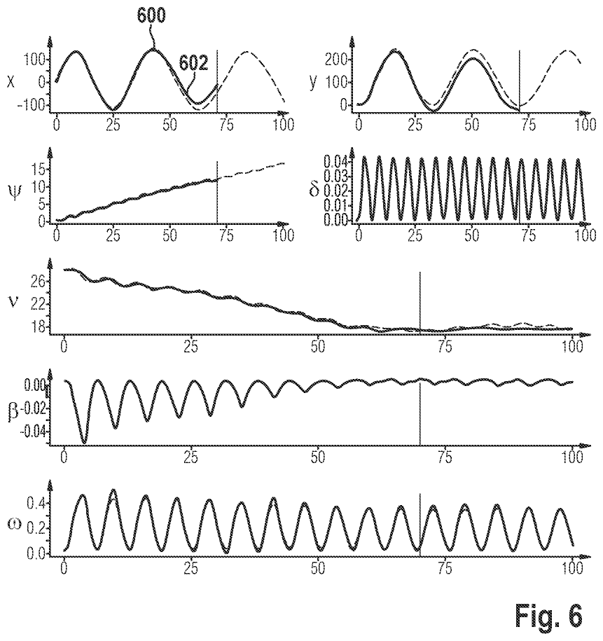

FIGS. 5 and 6 show a comparison of a conventional physical single-track model 404 (see FIG. 5) with a hybrid AI algorithm 206 generated according to the present invention (see FIG. 6). The reference data are shown in with the reference signs 500 and 600 and the model estimates with the reference signs 502, 602. The physical model 404 in FIG. 5 shows poor accuracy because the nonlinear tire-road contact is not taken into account due to computational complexity. The hybrid AI algorithm 206, on the other hand, shows a very accurate and stable extrapolation.

The hybrid vehicle dynamics model, which can preferably be used for lane departure warning systems or autonomous driving functions, therefore offers a plurality of advantages. The combination with a controller (e.g. model predictive controller) preferably results in a software function that can be provided within a control unit. The hybrid AI model according to the present invention combines the advantages of conventional purely physical or purely data-based models. The good fit to measurement data is provided by the AI-based component, whose optimal model structure is ascertained by at least one Auto-ML method. The model complexity can easily be controlled by changing the number of neurons in the hidden layer of the NN. The physical component 400, which is based purely on kinematics and does not comprise any uncertainties, also improves the accuracy of the extrapolation compared to a purely AI-based approach.

1-15. (canceled)

16. A computer-implemented method for generating a hybrid artificial intelligence algorithm using which a dynamic system behavior of a physical system can be modeled and/or regulated and/or controlled and/or adjusted and/or modified, the method comprising the following steps:
providing a system state vector that includes at least two system states of the physical system, wherein at least one of the at least two states can be calculated using at least one analytical and/or statistical equation, and wherein at least one other of the at least two states can be calculated using at least one artificial intelligence algorithm to be ascertained;
carrying out at least one automatic learning method for ascertaining a plurality of artificial intelligence algorithms using which at least the other of the at least two states can be calculated in each case; and
selecting at least one artificial intelligence algorithm from the plurality of artificial intelligence algorithms as a function of at least one selection criterion to generate the hybrid artificial intelligence algorithm coupled with the at least one equation.

17. The method according to claim 16, wherein the at least one analytical and/or statistical equation satisfies a predetermined complexity criterion

18. The method according to claim 16, wherein the at least one automatic learning method includes: (i) a neural architecture search and/or solution finder for solving ordinary differential equations, and/or (ii) a hyperparameter search, and/or (iii) a model structure search.

19. The method according to claim 16, wherein the selection criterion is determined by a predetermined complexity measure of each artificial intelligence algorithm of the plurality of artificial intelligence algorithms.

20. The method according to claim 16, wherein the selection criterion is determined: (i) by a predetermined measure of storage space, and/or (ii) by an execution time, and/or (iii) by an Akaike information criterion of each artificial intelligence algorithm of the plurality of artificial intelligence algorithms.

21. The method according to claim 16, wherein the at least one analytical and/or statistical equation is described by at least one differential equation.

22. The method according to claim 16, wherein the at least one analytical and/or statistical equation includes an equation term that can be calculated using the artificial intelligence algorithm to be ascertained.

23. The method according to claim 16, wherein the plurality of artificial intelligence algorithms is ascertained by carrying out the at least one automatic learning method in a parallelized manner.

24. The method according to claim 16, wherein the plurality of artificial intelligence algorithms is ascertained taking into account available computing resources, which are included as a loss function in a model ascertainment.

25. The method according to claim 16, wherein the at least two states can be described by: physical measured values and/or input data and/or output data and/or manipulated variables and/or sensor data.

26. The method according to claim 16, wherein the physical system is a motor vehicle or a heat pump.

27. The method according to claim 26, wherein the dynamic system behavior is described by a vehicle dynamics model or a dynamic energy distribution model.

28. An apparatus configured to generate a hybrid artificial intelligence algorithm using which a dynamic system behavior of a physical system can be modeled and/or regulated and/or controlled and/or adjusted and/or modified, the apparatus comprising:
a providing device configured to provide a system state vector that includes at least two system states of the physical system, wherein at least one of the at least two states can be calculated by means of at least one analytical and/or statistical equation, and wherein at least one other of the at least two states can be calculated by means of at least one artificial intelligence algorithm to be ascertained;
an evaluating and computing device configured to:
carry out at least one automatic learning method for ascertaining a plurality of artificial intelligence algorithms by means of which in each case the at least other of the at least two states can be calculated, and
select at least one artificial intelligence algorithm from the plurality of artificial intelligence algorithms as a function of at least one selection criterion to generate the hybrid artificial intelligence algorithm coupled with the at least one equation.

29. A physical system, comprising:
a motor vehicle or a heat pump, whose dynamic system behavior is at least partially modeled by a hybrid artificial intelligence algorithm, the hybrid artificial intelligence algorithm being generated by:
providing a system state vector that includes at least two system states of the physical system, wherein at least one of the at least two states can be calculated using at least one analytical and/or statistical equation, and wherein at least one other of the at least two states can be calculated using at least one artificial intelligence algorithm to be ascertained,
carrying out at least one automatic learning method for ascertaining a plurality of artificial intelligence algorithms using which at least the other of the at least two states can be calculated in each case, and
selecting at least one artificial intelligence algorithm from the plurality of artificial intelligence algorithms as a function of at least one selection criterion to generate the hybrid artificial intelligence algorithm coupled with the at least one equation.

30. A non-transitory computer-readable data carrier on which is stored program code of a computer program for generating a hybrid artificial intelligence algorithm using which a dynamic system behavior of a physical system can be modeled and/or regulated and/or controlled and/or adjusted and/or modified, the computer program, when executed by a computer, causing the computer to perform the following steps:
providing a system state vector that includes at least two system states of the physical system, wherein at least one of the at least two states can be calculated using at least one analytical and/or statistical equation, and wherein at least one other of the at least two states can be calculated using at least one artificial intelligence algorithm to be ascertained;
carrying out at least one automatic learning method for ascertaining a plurality of artificial intelligence algorithms using which at least the other of the at least two states can be calculated in each case; and
selecting at least one artificial intelligence algorithm from the plurality of artificial intelligence algorithms as a function of at least one selection criterion to generate the hybrid artificial intelligence algorithm coupled with the at least one equation.
